(19) United States
(12) Patent Application Publication
(10) Pub. No.: US 2025/0016966 A1
(43) Pub. Date: Jan. 9, 2025

(54) COOLER FOR POWER ELECTRONICS

(71) Applicant: Atieva, Inc., Newark, CA (US)

(72) Inventors: Barnaby James Gerard Lewis, San Francisco, CA (US); Bradley Lucas Hall, Newark, CA (US); Richard J. Biskup, Sunnyvale, CA (US)

(21) Appl. No.: 18/704,797

(22) PCT Filed: Oct. 24, 2022
(86) PCT No.: PCT/US2022/078588

§ 371 Date: Apr. 25, 2024

Related U.S. Application Data
(60) Provisional application No. 63/263,137, filed on Oct. 27, 2021.

(51) Int. Cl. H05K 7/20

(52) U.S. Cl. CPC H05K 7/20927; H05K 7/20254; H05K 7/20272; H05K 7/20509

(57) ABSTRACT

A cooler for power electronics comprises: a laminated structure having an inlet and an outlet, the laminated structure comprising a stack of planar members, wherein a first outermost member at an end of the stack forms a first heat exchange surface for mounting a first power electronics baseplate, wherein a second outermost member is positioned at an opposite end of the stack, wherein a first plurality of the planar members adjacent the first outermost member have openings that form a first heat exchange space within the stack, and wherein the inlet and the outlet are coupled to the first heat exchange space.

### CROSS-REFERENCE TO RELATED APPLICATION

This application claims priority to U.S. Patent Application No. 63/263,137, filed on Oct. 27, 2021, and entitled “COOLER FOR POWER ELECTRONICS,” the disclosure of which is incorporated by reference herein in its entirety.

### TECHNICAL FIELD

This document relates to a cooler for power electronics.

### BACKGROUND

Power electronics are used in a variety of situations. In electric vehicles, they can be included in an inverter that converts direct current from a high-voltage battery pack into alternating current for powering a propulsion motor, or to feed energy recovered from the motor to the battery pack. Similarly, power electronics can be used in non-mobile energy storage systems, for example when serving as a power solution for a house or another building. Common to these examples of uses is that the power electronics generate heat that may need to be managed in some way. Moreover, space constraints can be a factor, such that more compact solutions for thermal control may be favorable.

### SUMMARY

In an aspect, a cooler for power electronics comprises: a laminated structure having an inlet and an outlet, the laminated structure comprising a stack of planar members, wherein a first outermost member at an end of the stack forms a first heat exchange surface for mounting a first power electronics baseplate, wherein a second outermost member is positioned at an opposite end of the stack, wherein a first plurality of the planar members adjacent the first outermost member have openings that form a first heat exchange space within the stack, and wherein the inlet and the outlet are coupled to the first heat exchange space.

Implementations can include any or all of the following features. A second plurality of the planar members adjacent the first plurality of the planar members have openings that form an inlet manifold coupled to the inlet and to the first heat exchange space, wherein a first aperture is positioned between the inlet manifold and the first heat exchange space. The inlet manifold has a first width along a flow direction in the heat exchange space, and wherein the first aperture has a second width smaller than the first width. The first aperture is centered with regard to the inlet manifold. The second plurality of the planar members further form an outlet manifold coupled to the outlet and to the first heat exchange space, wherein the outlet manifold is parallel to the inlet manifold, wherein a second aperture is positioned between the outlet manifold and the first heat exchange space. The second aperture is not centered with regard to the outlet manifold, and wherein the second aperture is positioned away from the inlet manifold with regard to the outlet manifold. The outlet manifold has a first width along a flow direction in the first heat exchange space, and wherein the second aperture has a second width smaller than the first width. The inlet manifold comprises a single inlet manifold arm. The outlet manifold comprises respective outlet manifold arms on opposite sides of the single inlet manifold arm. The cooler further comprises structure inside the first heat exchange space, the structure separate from the planar members and including holes. The holes are periodically spaced in the structure, and wherein each of the holes is aligned with a corresponding pin. The cooler further comprises: a first opening in the first outermost member; and a first slot at an edge of a first planar member, the first slot aligned with the first opening, the first slot configured for receiving a square nut. The first planar member abuts the first outermost member, the cooler further comprising: a second opening in the first outermost member; and a second slot at an edge of a second planar member that abuts the first planar member and is positioned opposite from the first outermost member, the second slot aligned with the second opening. At least some of the planar members have different thicknesses from each other. The cooler is a double cooler for the first power electronics baseplate and a second power electronics baseplate, wherein the second outermost member forms a second heat exchange surface for mounting the second power electronics baseplate, wherein a second plurality of the planar members adjacent the second outermost member have openings that form a second heat exchange space within the stack, and wherein the inlet and the outlet are also coupled to the second heat exchange space.

### BRIEF DESCRIPTION OF DRAWINGS

FIG. 1 shows an example of a cooler for power electronics.

FIG. 2A schematically shows an example of a cooler with a power electronics baseplate, and FIG. 2B schematically shows an example of a double cooler with two power electronics baseplates.

FIG. 3 shows an example of power electronics that can be mounted to the cooler of FIG. 1.

FIG. 4 shows an example of a fluid path for coolant through the cooler of FIG. 1.

FIG. 5 schematically shows an example of a laminated structure comprising a stack of planar members.

FIG. 6 schematically shows an example of a cross section along the line A-A in FIG. 4.

FIG. 7 schematically shows an example of a cross section of a double cooler.

FIG. 8 shows an example of a cooler that has mounting structure for power electronics.

FIG. 9 conceptually shows a cooler that can provide increased heat transfer for a compact power unit.

FIG. 10 shows an example planar member that can be used with the cooler in FIG. 1.

FIG. 11 shows an example partial stack of planar members that can be used with the cooler in FIG. 1.

FIG. 12 shows an example cross section of the cooler in FIG. 1.

Like reference symbols in the various drawings indicate like elements.

### DETAILED DESCRIPTION

This document describes examples of systems and techniques for cooling power electrics in any of a variety of situations. In some implementations, a cooler can have a laminated structure that is made using a stack of planar members. Some of the planar members have openings in them such that cavities, passageways, manifolds, apertures, or other features are formed inside the laminated structure. This can provide a flexible cooler design that can be adapted for cooling a single set or multiple sets of power electronics modules. The cooler can have one or more features that improve the flow of coolant, and thereby the cooler's efficiency in transferring heat. The cooler can be made largely from components stamped from sheet stock, which can reduce manufacturing costs. The cooler can provide improved compactness also in demanding implementations such as high-performance electric vehicles where a substantial number of switches are used in the inverter, thereby generating a significant amount of heat. As such, more compact power units can be provided by the present disclosure.

Examples described herein refer to power electronics. As used herein, power electronics includes any circuitry that converts electric power using solid-state electronics (e.g., one or more semiconductor devices). A power electronics component can include one or more transistors. In some implementations, a metal-oxide semiconductor field-effect transistor (MOSFET) can be used. For example, the power electronics can include one or more silicon carbide MOSFETs. In some implementations, an insulated gate bipolar transistor (IGBT) can be used. The circuitry of the power electronics component can include one or more elements in addition to a switch, including, but not limited to, a diode, resistor, and/or capacitor.

Examples described herein refer to coolant. As used herein, coolant includes any fluid used to regulate temperature. The coolant can include water (optionally with one or more additives), to name just one example. Coolant that passes through a cooler as described herein can be circulated in a thermal system. For example, such a system can also include one or more features for releasing heat, such as by conduction, convection, and/or radiation.

Examples described herein use the term “couple” or a variation of it when describing that a first feature and a second feature are coupled to each other. As used herein, being coupled indicates that the features are in fluid communication with each other. For example, coolant can flow from the first feature to the second feature, and/or can flow from the second feature to the first feature.

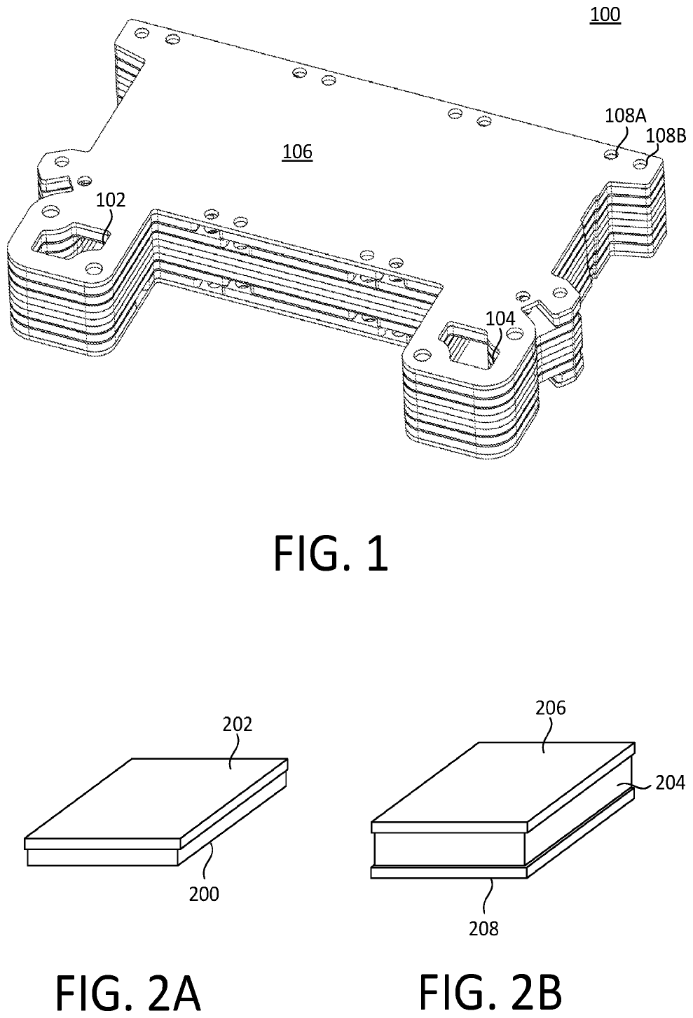

FIG. 1 shows an example of a cooler 100 for power electronics. The cooler 100 can be used with one or more other examples described elsewhere herein. The cooler 100 is made using a laminated structure and has a port 102 and a port 104. Each of the ports 102 and 104 is an opening into an interior of the cooler 100. For example, the port 102 can serve as an inlet for coolant and the port 104 as an outlet, or vice versa. Each of the ports 102 and 104 can be configured for attachment to one or more types of conduit and/or to another component of a thermal system.

The cooler 100 has a heat exchange surface 106. In some implementations, the heat exchange surface 106 is formed by an outermost planar member at an end of the stack that makes up the laminated structure. The heat exchange surface 106 can serve as a thermal interface for cooling one or more power electronics modules (not shown). For example, a heat exchange space can be formed inside the cooler 100 adjacent the heat exchange surface 106, the heat exchange space being coupled to the ports 102 and 104. At the outermost planar member (e.g., within the heat exchange surface 106), the cooler can have one or more features for attaching a baseplate of the power electronics module(s). Here, the outermost planar member has openings 108A and 108B, for example, among others.

FIG. 2A schematically shows an example of a cooler 200 with a power electronics baseplate 202, and FIG. 2B schematically shows an example of a double cooler 204 with power electronics baseplates 206 and 208. The coolers 200 or 204 can be used with one or more other examples described elsewhere herein. The power electronics baseplates 202, 206, or 208 can be used with one or more other examples described elsewhere herein.

The cooler 200 can be referred to as a single model. The power electronics baseplate 202 can be mounted to the sole heat exchange surface formed on the exterior of the cooler 200. An inlet or outlet of the cooler 200 are not shown for simplicity. The cooler 200 can provide a low-cost, compact solution for efficiently cooling the component(s) of the power electronics baseplate 202. For example, the cooler 200 may not extend past the exterior dimensions of the power electronics baseplate 202.

In the double cooler 204, each of the power electronics baseplates 206 and 208 can be mounted to a respective heat exchange surface formed on the exterior of the double cooler 204. For example, the heat exchange surfaces are here formed at opposing main surfaces of the double cooler 204. In some implementations, a respective heat exchange space can be formed inside the double cooler 204 adjacent each of the heat exchange surfaces. The respective components of the power electronics baseplates 206 and 208 can be similar to each other, or they can be of different designs. An inlet or outlet of the double cooler 204 are not shown for simplicity. The double cooler 204 can provide a low-cost, compact solution for efficiently cooling the components of the power electronics baseplates 206 and 208. For example, the double cooler 204 may not extend past the exterior dimensions of either of the power electronics baseplates 206 and 208.

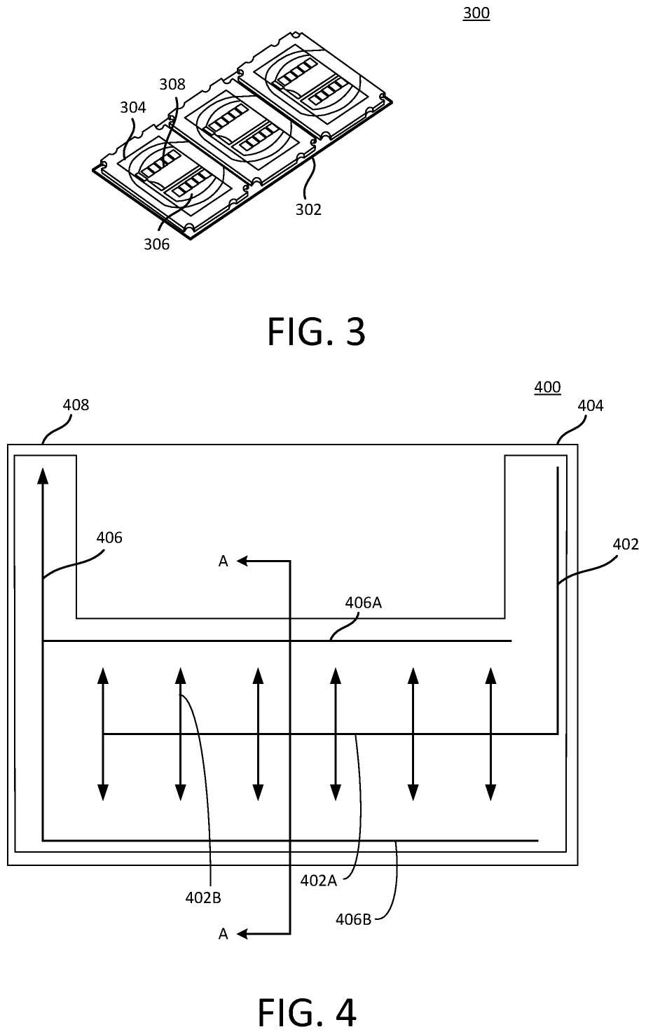

FIG. 3 shows an example of power electronics 300 that can be mounted to the cooler 100 of FIG. 1, for example. The power electronics 300 can be used with one or more other examples described elsewhere herein. The power electronics 300 includes a baseplate 302 that may have a flat main surface that is currently not visible. The baseplate 302 can be made of a thermally conductive material, including, but not limited to, metal (e.g., copper). At least one module 304 can be assembled to a surface of the baseplate 302. Here, the power electronics 300 includes three modules 304. The module 304 can include one or more rows 306 of switches 308. Here, the module 304 includes two rows 306 each having five switches 308. The switches 308 within the row 306 can be formed on dies. The switches 308 can be MOSFETs or IGBTs, to name just two examples. The power electronics 300 can be mounted with its flat main surface abutting a heat exchange surface of any of the coolers described herein.

FIG. 4 shows an example of a fluid path 400 for coolant through the cooler 100 of FIG. 1, for example. The fluid path 400 can be used with one or more other examples described elsewhere herein. For example, the fluid path 400 can illustrate the interior structure of the cooler 100 as viewed in a direction through the heat exchange surface 106.

The fluid path 400 includes an inlet path 402. In some implementations, the inlet path 402 has substantially an L-shape. The inlet path 402 can begin at an inlet 404, form at least one arm 402A (e.g., a single arm) within an inlet manifold, and thereafter travel along one or more flow directions 402B that represent the end of the inlet path 402. The flow directions 402B can be approximately perpendicular to the arm 402A. For example, coolant passing in the flow directions 402B can travel along an inside of a heat exchange surface of the cooler, thereby facilitating heat exchange where the coolant absorbs thermal energy.

The fluid path 400 includes an outlet path 406. In some implementations, the outlet path 406 has substantially an F-shape. The outlet path 406 can begin at one or more of the flow directions 402B, forming one or more arms 406A-406B (e.g., two arms) within at least one respective outlet manifold. The arms 406A-406B can be substantially parallel to each other. For example, the arms 406A-406B can be situated on opposite sides of the arm 402A of the inlet path 402. The outlet path 406 can terminate at an outlet 408.

The flow directions 402B can provide efficient heat exchange. In some implementations, the flow directions 402B can line up with where the individual rows of switches are positioned at the power electronics unit. For example, the flow directions 402B can be arranged so that each die of the power electronics receives a parallel flow of coolant.

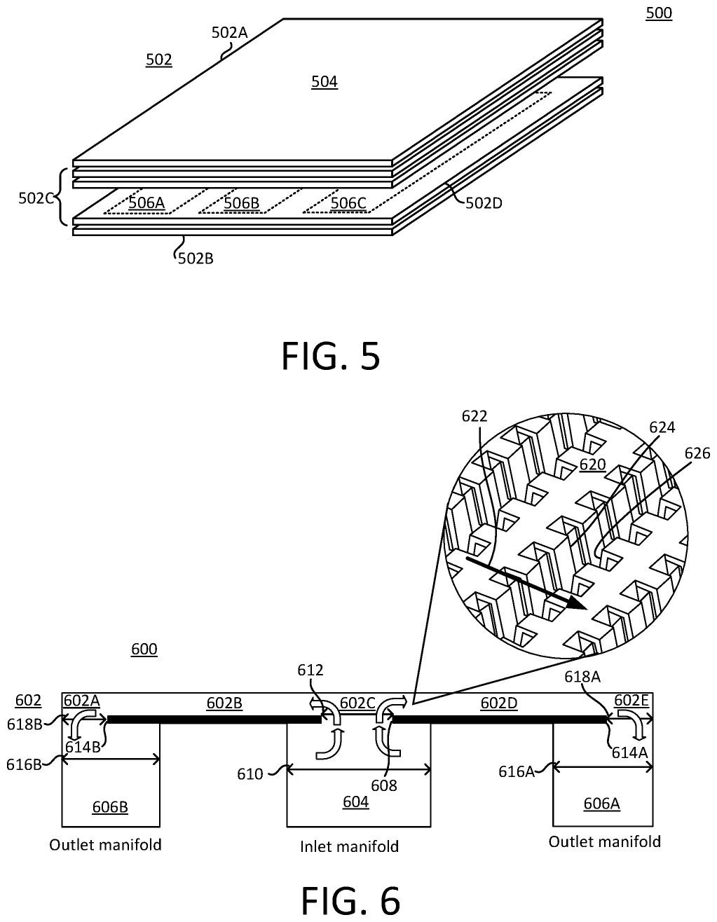

FIG. 5 schematically shows an example of a laminated structure 500 comprising a stack of planar members 502. The laminated structure 500 and/or any of the planar members 502 can be used with one or more other examples described elsewhere herein. For example, any or all coolers described herein can include the laminated structure 500.

The planar members 502 can include multiple planar elements that are formed from sheet stock of a material. In some implementations, the material is a metal or a metal alloy. Aluminum or an aluminum alloy can be used, to name just a few examples. The planar members 502 can have any shape, including, but not limited to, the shape of the cooler 100 in FIG. 1. The planar members 502 can all include a common material and/or have a common thickness. As another example, at least some of the planar members 502 can have different thicknesses from each other.

The planar members 502 here include an outermost member 502A at an end of the stack. For example, the outermost member 502A can form a heat exchange surface 504. The planar members 502 here include an outermost member 502B at an opposite end of the stack. For example, the outermost member 502B can form another heat exchange surface. The planar members 502 include planar members 502C that are positioned between the outermost members 502A-502B. Some or all of the planar members 502C have one or more openings. Here, a planar member 502D is shown to have openings 506A-506C. For example, the opening 506B can form part of an inlet manifold for coolant on its way toward the heat exchange surface 504. As another example, the openings 506A and 506C can form part of an outlet manifold for coolant on its way out of the laminated structure 500.

The planar members 502 can be assembled to form the laminated structure 500. In some implementations, brazing can be performed. For example, pre-clad plates of metal (e.g., aluminum) can be stacked into an assembly and be heated in an oven to join them to each other.

The above examples illustrate that a cooler for power electronics (e.g., any of the coolers 100, 200, or 204), can include a laminated structure (e.g., the laminated structure 500) having an inlet and an outlet (e.g., the ports 102 and 104). The laminated structure can include a stack of planar members (e.g., the planar members 502). A first outermost member (e.g., the outermost member 502A) at an end of the stack can form a first heat exchange surface (e.g., the heat exchange surface 106) for mounting a first power electronics baseplate (e.g., the power electronics baseplate 302). A second outermost member (e.g., the outermost member 502B) can be positioned at an opposite end of the stack. A first plurality of the planar members adjacent the first outermost member (e.g., some of the planar members 502C) can have openings that form a first heat exchange space within the stack (e.g., to accommodate coolant traveling substantially along the flow directions 402B). The inlet and the outlet can be coupled to the first heat exchange space (e.g., by the inlet path 402 and the outlet path 406, respectively).

FIG. 6 schematically shows an example 600 of a cross section along the line A-A in FIG. 4. The example 600 can be used with one or more other examples described elsewhere herein. The example 600 illustrates how coolant can flow through a cooler for efficient heat exchange in a compact solution.

The cooler in the example 600 provides a heat exchange space 602 where the coolant can absorb heat from power electronics as it flows. Initially, coolant can enter an inlet manifold 604 that is coupled to the heat exchange space 602. For example, the inlet manifold 604 can be formed by openings in respective planar members of a laminated structure. After traversing the heat exchange space 602, the coolant can enter one or more outlet manifolds 606A-606B that are coupled to the heat exchange space 602. For example, the outlet manifolds 606A-606B can be formed by respective openings in the planar members.

In some circumstances, the coolant distribution through the heat exchange space 602 can have a somewhat uneven flow. For example, it can be observed that there is relatively more flow in portions 602B and 602D of the heat exchange space 602, whereas portions 602A, 602C, and 602E thereof can have relatively less or no flow. This lack of coolant flow indicates that there is reduced heat exchange in the portions 602A, 602C, and 602E of the heat exchange space 602.

One or more apertures can be provided to improve the coolant distribution. In some implementations, an aperture 608 can be positioned between the inlet manifold 604 and the heat exchange space 602 (e.g., so as to face the portion 602C thereof). The aperture 608 can be centered with regard to the inlet manifold 604. For example, the inlet manifold 604 can have a width 610 measured along a direction parallel to a flow direction in the heat exchange space 602, and the aperture 608 can have a width 612 smaller than the width 610. The aperture 608 can improve the coolant flow in at least the portion 602C of the heat exchange space 602. The aperture 608 can be formed by one or more planar members of the laminated structure.

In some implementations, an aperture 614A can be positioned between the outlet manifold 606A and the heat exchange space 602 (e.g., so as to face the portion 602E thereof). The aperture 614A may not be centered with regard to the outlet manifold 606A. The aperture 614A may be positioned away from the inlet manifold 604 with regard to the outlet manifold 606A. The outlet manifold 606A can have a width 616A measured along a direction parallel to a flow direction in the heat exchange space 602, and the aperture 614A can have a width 618A smaller than the width 616A. The aperture 614A can improve the coolant flow in at least the portion 602E of the heat exchange space 602. The aperture 614A can be formed by one or more planar members of the laminated structure.

In some implementations, an aperture 614B can be positioned between the outlet manifold 606B and the heat exchange space 602 (e.g., so as to face the portion 602A thereof). The aperture 614B may not be centered with regard to the outlet manifold 606B. The aperture 614B may be positioned away from the inlet manifold 604 with regard to the outlet manifold 606B. The outlet manifold 606B can have a width 616B measured along a direction parallel to a flow direction in the heat exchange space 602, and the aperture 614B can have a width 618B smaller than the width 616B. The aperture 614B can improve the coolant flow in at least the portion 602A of the heat exchange space 602. The aperture 614B can be formed by one or more planar members of the laminated structure.

One or more features can be placed in the heat exchange space 602 to control the coolant flow and/or improve the heat transfer. In some implementations, structure 620 (here shown as an inset) can be provided inside the heat exchange space 602. The structure 620 can be separate from (e.g., not formed by) the planar members that define the heat exchange space 602. For example, the structure 620 can be brazed to one or more of the planar members during assembly. The structure 620 can be oriented in any direction. For example, an arrow 622 shown relative to the structure 620 can be aligned with (e.g., parallel or antiparallel to) the flow direction in the heat exchange space 602. The structure can include holes 624. The holes 624 can be periodically spaced in the structure 620, for example to be aligned with a corresponding one of pins 626. The structure 620 can be used with one or more other coolers described herein.

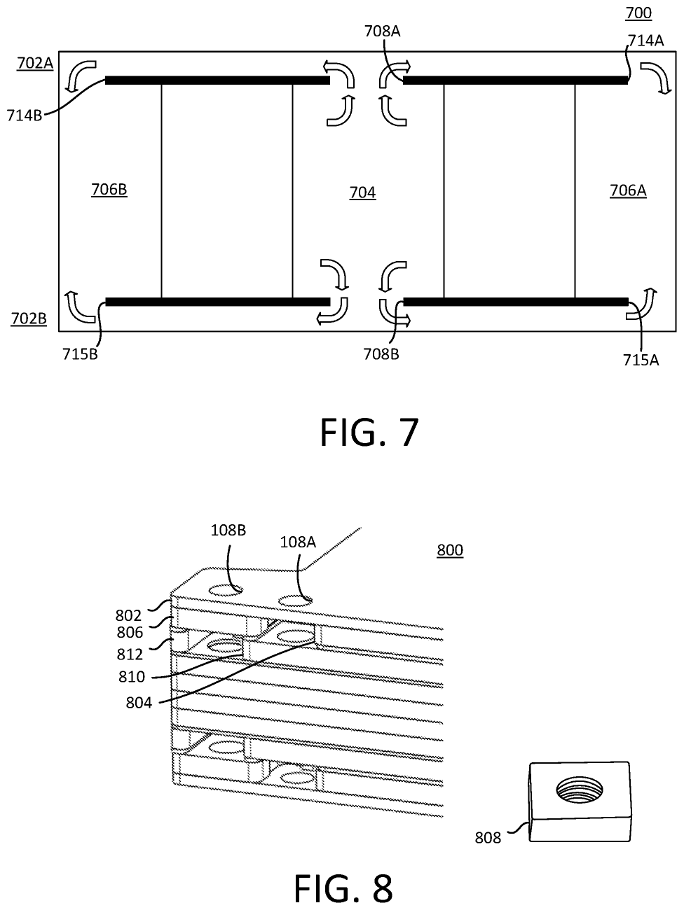

FIG. 7 schematically shows an example 700 of a cross section of a double cooler. The example 700 can be used with one or more other examples described elsewhere herein. The example 700 illustrates how coolant can flow through a double cooler for efficient heat exchange in a compact solution.

The double cooler in the example 700 provides heat exchange spaces 702A-702B where the coolant can absorb heat from power electronics as it flows. The double cooler includes an inlet manifold 704 that is coupled to each of the heat exchange spaces 702A-702B. For example, the inlet manifold 704 can be formed by openings in respective planar members of a laminated structure. The double cooler includes outlet manifolds 706A-706B that are each coupled to both of the heat exchange spaces 702A-702B. For example, the outlet manifolds 706A-706B can be formed by respective openings in the planar members.

The double cooler can include an aperture 708A positioned between the inlet manifold 704 and the heat exchange space 702A. The double cooler can include an aperture 708B positioned between the inlet manifold 704 and the heat exchange space 702B. The double cooler can include an aperture 714A positioned between the outlet manifold 706A and the heat exchange space 702A. The double cooler can include an aperture 715A positioned between the outlet manifold 706A and the heat exchange space 702B. The double cooler can include an aperture 714B positioned between the outlet manifold 706B and the heat exchange space 702A. The double cooler can include an aperture 715B positioned between the outlet manifold 706B and the heat exchange space 702B. Each of the apertures 708A-708B, 714A-714B, and 715A-715B can be formed by a respective one or more planar members of the laminated structure.

FIG. 8 shows an example 800 of a cooler that has mounting structure for power electronics. The example 800 can be used with one or more other examples described elsewhere herein. For example, the example 800 can be used with the cooler 100 in FIG. 1.

The cooler includes the opening 108A in an outermost member 802. The cooler includes a slot 804 at an edge of a planar member 806. For example, the slot 804 can be stamped into the planar member 806 (e.g., in connection with forming one or more other openings, such as for a heat exchange space). The slot 804 is aligned with the opening 108A. The slot 804 is configured for receiving a square nut 808. The square nut can include internal threads. In some implementations, this can allow insertion of a fastener (e.g., a bolt) through the opening 108A to be secured using the square nut 808. For example, this can facilitate attachment of a power electronics baseboard to the outermost member 802.

The planar member 806 can abut the outermost member 802. The cooler can include a slot 810 at an edge of a planar member 812. The planar member 812 abuts the planar member 806 and is positioned opposite from the outermost member 802. The slot 810 can be stamped into the planar member 812 (e.g., in connection with forming one or more other openings, such as for a heat exchange space). The slot 810 is aligned with the opening 108B. The slot 810 is configured for receiving another one of the square nut 808. As such, the planar member 812 can also or instead be used in attaching a power electronics baseboard.

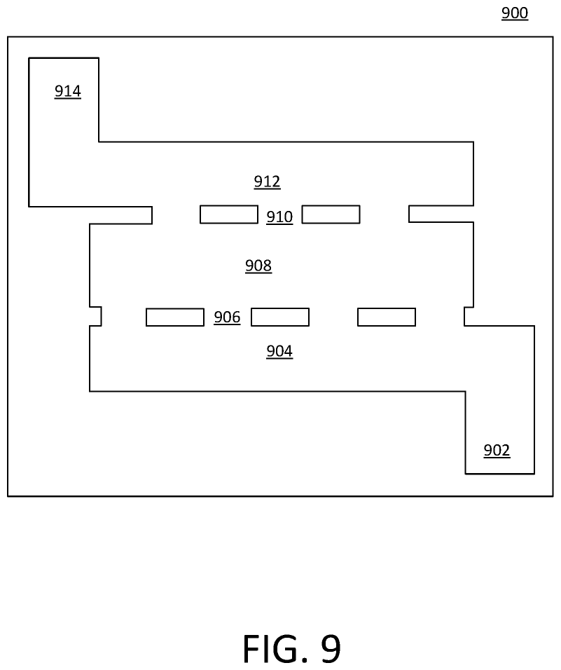

FIG. 9 conceptually shows a cooler 900 that can provide increased heat transfer for a compact power unit. The cooler 900 can be used with one or more other examples described elsewhere herein. The cooler 900, such as the individual structures to be exemplified in the following, can be formed by individual planar members that are stacked to form a laminated structure.

The cooler 900 includes an inlet 902 for coolant. The cooler 900 includes an inlet manifold 904 coupled to the inlet 902. The cooler 900 has apertures 906 between the inlet manifold 904 and a heat exchange zone 908. For example, the heat exchange zone extends along the inside of a heat exchange surface of the cooler 900. The cooler 900 includes apertures 910 between the heat exchange zone 908 and an outlet manifold 912. The outlet manifold 912 is coupled to an outlet 914. Two or more of the inlet manifold 904, heat exchange zone 908, and outlet manifold 912 can be situated in different planes from each other. For example, the inlet manifold 904 and the outlet manifold 912 can be positioned essentially at a common level of the cooler 900. As another example, the heat exchange zone 908 can be positioned at a different level than at least one of the inlet manifold 904 or the outlet manifold 912.

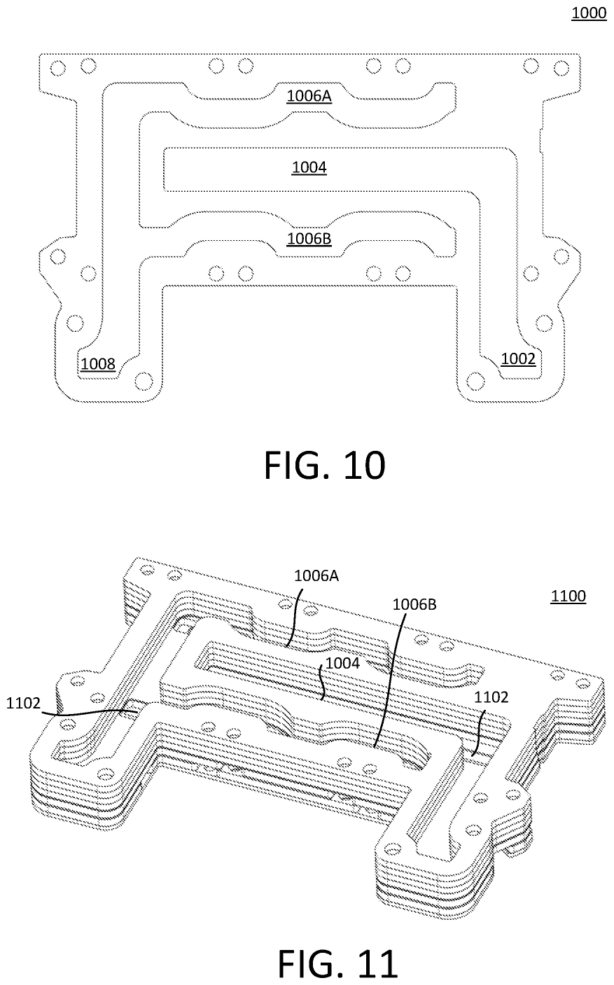

FIG. 10 shows an example planar member 1000 that can be used with the cooler 100 in FIG. 1. The planar member 1000 can form a fluid path for coolant. The planar member 1000 has an inlet path that begins at an inlet 1002, and forms at least one arm 1004 (e.g., a single arm) within an inlet manifold. In some implementations, an outlet path has substantially an F-shape. The outlet path can form one or more arms 1006A-1006B (e.g., two arms) within at least one respective outlet manifold. The outlet path can end at an outlet 1008.

FIG. 11 shows an example partial stack 1100 of planar members that can be used with the cooler 100 in FIG. 1. The partial stack 1100 shows the arms 1004, 1006A, and 1006B. The partial stack 1100 can form at least one recess 1102 in one or more of the arms 1004, 1006A, and 1006B, or otherwise in a manifold.

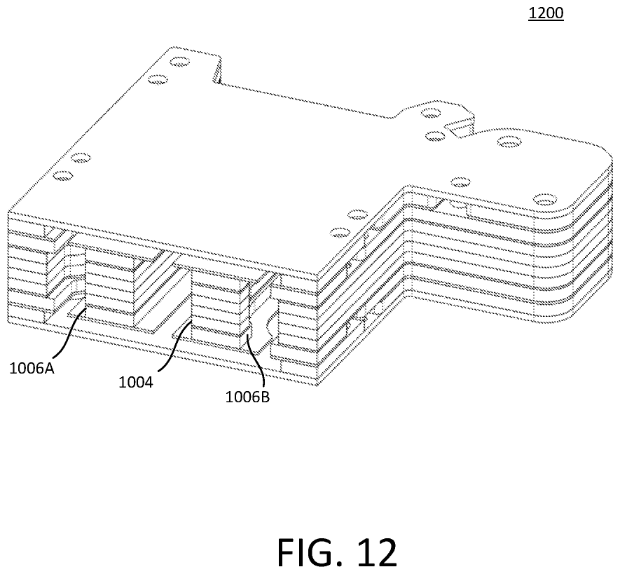

FIG. 12 shows an example cross section 1200 of the cooler 100 in FIG. 1. The cross section 1200 shows the arms 1004, 1006A, and 1006B.

The terms “substantially” and “about” used throughout this Specification are used to describe and account for small fluctuations, such as due to variations in processing. For example, they can refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%. Also, when used herein, an indefinite article such as “a” or “an” means “at least one.”

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein.

A number of implementations have been described. Nevertheless, it will be understood that various modifications may be made without departing from the spirit and scope of the specification.

In addition, the logic flows depicted in the figures do not require the particular order shown, or sequential order, to achieve desirable results. In addition, other processes may be provided, or processes may be eliminated, from the described flows, and other components may be added to, or removed from, the described systems. Accordingly, other implementations are within the scope of the following claims.

While certain features of the described implementations have been illustrated as described herein, many modifications, substitutions, changes and equivalents will now occur to those skilled in the art. It is, therefore, to be understood that appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. A cooler for power electronics, the cooler comprising:
a laminated structure having an inlet and an outlet, the laminated structure comprising a stack of planar members, wherein a first outermost member at an end of the stack forms a first heat exchange surface for mounting a first power electronics baseplate, wherein a second outermost member is positioned at an opposite end of the stack, wherein a first plurality of the planar members adjacent the first outermost member have openings that form a first heat exchange space within the stack, and wherein the inlet and the outlet are coupled to the first heat exchange space.

2. The cooler of claim 1, wherein a second plurality of the planar members adjacent the first plurality of the planar members have openings that form an inlet manifold coupled to the inlet and to the first heat exchange space, wherein a first aperture is positioned between the inlet manifold and the first heat exchange space.

3. The cooler of claim 2, wherein the inlet manifold has a first width along a flow direction in the heat exchange space, and wherein the first aperture has a second width smaller than the first width.

4. The cooler of claim 2, wherein the first aperture is centered with regard to the inlet manifold.

5. The cooler of claim 4, wherein the second plurality of the planar members further form an outlet manifold coupled to the outlet and to the first heat exchange space, wherein the outlet manifold is parallel to the inlet manifold, wherein a second aperture is positioned between the outlet manifold and the first heat exchange space.

6. The cooler of claim 5, wherein the second aperture is not centered with regard to the outlet manifold, and wherein the second aperture is positioned away from the inlet manifold with regard to the outlet manifold.

7. The cooler of claim 5, wherein the outlet manifold has a first width along a flow direction in the first heat exchange space, and wherein the second aperture has a second width smaller than the first width.

8. The cooler of claim 5, wherein the inlet manifold comprises a single inlet manifold arm.

9. The cooler of claim 8, wherein the outlet manifold comprises respective outlet manifold arms on opposite sides of the single inlet manifold arm.

10. The cooler of claim 1, further comprising structure inside the first heat exchange space, the structure separate from the planar members and including holes.

11. The cooler of claim 10, wherein the holes are periodically spaced in the structure, and wherein each of the holes is aligned with a corresponding pin.

12. The cooler of claim 1, further comprising:
a first opening in the first outermost member; and
a first slot at an edge of a first planar member, the first slot aligned with the first opening, the first slot configured for receiving a square nut.

13. The cooler of claim 12, wherein the first planar member abuts the first outermost member, the cooler further comprising:
a second opening in the first outermost member; and
a second slot at an edge of a second planar member that abuts the first planar member and is positioned opposite from the first outermost member, the second slot aligned with the second opening.

14. The cooler of claim 1, wherein at least some of the planar members have different thicknesses from each other.

15. The cooler of claim 1, wherein the cooler is a double cooler for the first power electronics baseplate and a second power electronics baseplate, wherein the second outermost member forms a second heat exchange surface for mounting the second power electronics baseplate, wherein a second plurality of the planar members adjacent the second outermost member have openings that form a second heat exchange space within the stack, and wherein the inlet and the outlet are also coupled to the second heat exchange space.
